(19) United States
(12) Patent Application Publication
(10) Pub. No.: US 2007/0205521 A1
(43) Pub. Date: Sep. 6, 2007

(54) Encapsulation of Semiconductor Components

(75) Inventor: Kevin L. Robinson, Clay, NY (US)

Correspondence Address: BOND, SCHOENECK & KING, PLLC, ONE LINCOLN CENTER, SYRACUSE, NY, 13202-1355, US

(73) Assignee: LOCKHEED MARTIN CORPORATION, Bethesda, MD (US)

(21) Appl. No.: 11/307,225

(22) Filed: Jan. 27, 2006

(51) Int. Cl. H01L 23/28

(52) U.S. Cl. 257/787

(57) ABSTRACT

An embodiment of the invention is directed to an encapsulated semiconductor device package. The package includes a semiconductor substrate, at least one semiconductor device wherein a portion of the device is on an exposed surface of the substrate and a non-patterned layer of nanocrystalline diamond covering the portion of the device on the exposed surface of the substrate. The layer of nanocrystalline diamond covering the portion of the device is intended to provide a hermetic seal that is more reliable and efficient than traditional materials and methods used for encapsulating semiconductor devices. The layer of nanocrystalline diamond is also intended as a means to make an integrated circuit tamper-proof by virtue of the layer opacity and material hardness of the nanocrystalline diamond film. A method for encapsulating a semiconductor device of an integrated circuit (IC) involves providing a semiconductor IC chip including a semiconductor device and depositing a non-patterned nanocrystalline diamond film over at least a portion of a surface of the semiconductor IC chip containing the semiconductor device.

### BACKGROUND OF THE INVENTION

1. Field of the Invention

Embodiments of the invention are directed to the field of semiconductor component packaging and encapsulated semiconductor components. More particularly, embodiments of the invention are directed to hermetically encapsulated semiconductor components and tamper-proof semiconductor components including, e.g., monolithic microwave integrated circuits (MMICs), and to methods for obtaining said components.

2. Description of Related Art

Semiconductor devices, integrated circuits (ICs) and semiconductor integrated circuit (IC) devices such as, e.g., monolithic microwave integrated circuits (MMICs), and many others, all of which will hereinafter be referred to as semiconductor components, are ubiquitous in our modern society. They will be found in many every day devices as well as in the most sophisticated civilian and military technology; for example, space craft control and military surveillance. Accordingly, semiconductor IC technology plays a crucial role in advancing our civilization. We critically depend on processes and apparatus made possible by semiconductor IC technology.

Due to their ubiquity, various semiconductor components are inured with essential attributes that include the following: they must be highly dependable, extremely secure (i.e., tamper-proof) and process and cost efficient to make. For instance, a single failure of an IC-controlled automotive air bag cannot be considered acceptable. Likewise, the potential to reverse engineer a piece of captured, sophisticated military communications equipment could be hazardous to our national security. At the same time, enormous quantities of semiconductor components need to be manufactured efficiently.

As used herein, the term ‘encapsulation’ refers to protecting a semiconductor component from external influences. Thus, the term may refer to passivation or, more particularly as used herein, refers to hermetically sealing and/or tamper-proofing a semiconductor component. The term may apply to wafer level packaging, chip scale packaging, or otherwise encapsulating an exposed circuit or feature of a semiconductor component. The current processes and materials for encapsulating semiconductor components, however, do not guarantee fail safe results despite extremely high cost. A MEMS sensor in an automotive air bag system and MEMS RF switches illustrate the reliability requirements at issue; these components may require hermetically sealed semiconductor chip packages having operating lifetimes of 10 to 30 years. Similarly, existing semiconductor circuit passivation coatings can be etched away relatively easily to expose the circuit, thus compromising the security aspect of such a coating.

Various types of encapsulation materials and methods known in the art include: epoxy adhesive cover binding (‘GLOB’); the use of liquid crystal polymer substrates and caps; the use of photo-patternable polymer BenzoCycloButene (BCB); glass frit sealing; metal plug sealing; solder reflow sealing; covalent bonding and others. Certain techniques/materials are more or less effective for their intended purpose. Their selection may be based on market needs and performance lifetimes. In any event, the challenges of hermetic packaging and secure, tamper-proof encapsulation are well documented and known in the art. A conventional method of securing an MMIC in a semiconductor component involves the use of a silver filled epoxy to bond the MMIC. This reportedly led to degraded performance of the MMIC over time because as the epoxy oxidizes the impedance of the MMIC device changes. A solution identified in U.S. Pat. No. 6,472,748 (the disclosure of which is hereby incorporated by reference in its entirety to the fullest extent allowed by applicable patent laws and rules) involved encapsulating the MMIC device in a protective container when deployed in a circuit in order to protect the device from degraded performance, such as due to the aforementioned oxidation of the bonding agent. As disclosed therein, a container constructed using a top, such as a ceramic lid having a cavity disposed therein to envelope the MMIC, and the circuit board or ground plane as a base may be used. However, the use of such a container adds size as well as expense to the MMIC circuit and, therefore, may not be an acceptable solution in many commercial situations. The '748 patent further disclosed an alternative solution that involved sealing the MMIC in a resin, such as a polymeric resin, e.g., epoxy resin, pejoratively referred to as “GLOB” or “GLOB TOP” because of its seemingly arbitrary dollop application. This solution provided the advantage of utilizing commonly available items, such as epoxy resin, was relatively easy to apply, and provided a seal suitable for preventing undesired oxidation of the bonding agent. However, the presence of the protective resin itself has been found to affect the performance characteristics of the MMIC. Specifically, the application of an epoxy resin completely encapsulating a MMIC, although providing protection of the MMIC device and connections thereto, was found to affect the impedance of the device, resulting in appreciable mismatches between the device and additional circuitry coupled thereto. Although the performance characteristic changes due to the application of the protective resin were often acceptable at lower frequencies, such as 12-18 GHz, the changes due to the application of the protective resin often become intolerable at the higher frequency range of 20-100 GHz characteristic of MMICs.

In view of the foregoing identified shortcomings in the field of semiconductor component encapsulation packaging, the inventor has recognized the need for improvements in semiconductor component packaging processes and packaged semiconductor components. Particular targets for improvement include hermetic encapsulation, tamper-proof packaging, maintaining or improving process and cost efficiency, maintaining or improving performance characteristics, and maintaining or improving packaging size.

The interested reader is referred to the following references for background information related to semiconductor component packaging: The Impact of CSP's on Encapsulation Materials (www.chipscalereview.com/issues/0398/Stefanojelstad1.htm); Wong, Polymers for Encapsulation: Materials Processes and Reliability (www.chipscalereview.com/issues/0398/Wong1.htm); Riley, Wafer-level Hermetic Cavity Packaging (www.flipchips.com/tutorial43.html); and Tutorial 31 (www.flipchips.com/tutorial31.html). The entire subject matter disclosed in these references is hereby incorporated by reference to the fullest extent allowed by applicable patent laws and rules.

Relatively recent developments in nanotechnology may provide improved as well as new solutions to existing technological challenges. One such area of development deals with materials and processes relating to nanocrystalline diamond film deposition on substrates, microtips and other objects. More particularly, Ultrananocrystalline™ diamond (UNCD™) is the name for thin-film diamond material grown through a patented plasma-enhanced chemical vapor deposition process. UNCD is crystalline diamond consisting of nano-sized grains. The physical, chemical, electrical and other characteristics of nanocrystalline diamond film and UNCD in particular drive their current and prospective applications. Gruen and his colleagues can be credited with the principle patents and advancements relating to nanocrystalline diamond thin film deposition. The subject matter of U.S. Pat. Nos. 5,209,916; 5,370,855; 5,620,512; and U.S. Publication No. 20020114756 is hereby incorporated by reference in its entirety to the fullest extent allowed by applicable patent laws and rules. The interested reader is further referred to the Nanostructured Thin Film website of Argonne National Laboratory (http://www.chemistry.anl.gov/MSD/ntf.htm) and to the Internet description provided by Advanced Diamond Technologies, Inc. (http://www.thindiamond.com).

In general terms, U.S. Pat. No. 5,209,916 discloses a method of forming a nanocrystalline diamond film on a substrate. The method involves providing a substrate surface covered with a fullerene or diamond coating, positioning a fullerene in an ionization source, creating a fullerene vapor, ionizing fullerene molecules, accelerating the fullerene ions to energies above 250 eV to form a fullerene ion beam, impinging the fullerene ion beam on the substrate surface and continuing these steps to obtain a diamond thickness on the substrate. U.S. Pat. No. 5,370,855 discloses a method of forming synthetic hydrogen defect free diamond or diamond like films on a substrate. The method involves providing vapor containing fullerene molecules with or without an inert gas, providing a device to impart energy to the fullerene molecules, fragmenting at least in part some of the fullerene molecules in the vapor or energizing the molecules to incipient fragmentation, ionizing the fullerene molecules, and impinging ionized fullerene molecules on the substrate to assist in causing fullerene fragmentation to obtain a thickness of diamond on the substrate. U.S. Pat. No. 5,620,512 discloses a method and system for manufacturing nanocrystalline diamond film. The method involves forming a fullerene vapor, providing a noble gas stream and combining the gas with the fullerene vapor, passing the combined fullerene vapor and noble gas carrier stream into a chamber, forming a plasma in the chamber causing fragmentation of the fullerene and deposition of a diamond film on a substrate. U.S. Publication No. 20020114756 discloses a method for controlling the crystallite size and growth rate of plasma-deposited nanocrystalline diamond films. A plasma is established at a pressure in excess of about 55 Torr with controlled concentrations of hydrogen up to about 98% by volume, of unsubstituted hydrocarbons up to about 3% by volume and an inert gas of one or more of the noble gases and nitrogen up to about 98% by volume. The volume ratio of inert gas to hydrogen is preferably maintained at greater than about 4, to deposit a diamond film on a suitable substrate. The diamond film is deposited with a predetermined crystallite size and at a predetermined growth rate.

The inventor has recognized the advantages and benefits of applying the aforementioned technology relating to nanocrystalline diamond film to packaging and encapsulation of semiconductor components. These advantages and benefits and others will become more evident to persons skilled in the art in view of the following description and drawings.

### SUMMARY OF THE INVENTION

Embodiments of the invention are directed to hermetically encapsulated semiconductor components, tamper-proof semiconductor components, and methods for obtaining said components.

According to an embodiment of the invention, an encapsulated semiconductor device package includes a semiconductor substrate, at least one semiconductor device having a portion of the device on an exposed surface of the substrate, and a non-patterned layer of nanocrystalline diamond (nanocrystalline diamond film) encapsulating the portion of the device on the exposed surface of the substrate. More particularly, the nanocrystalline diamond is ultrnanocrystalline diamond (UNCD) as that term is defined in the art. In an aspect of the embodiment, the encapsulated semiconductor device package is hermetically sealed by the film layer of nanocrystalline diamond. In another aspect, the encapsulated semiconductor device package is tamper-proof. According to this aspect, the nanocrystalline diamond film is opaque depending upon its deposited thickness and has material characteristics that would result in destruction of the semiconductor circuitry in the event its removal was attempted. In an exemplary aspect, the semiconductor device is a microwave monolithic integrated circuit (MMIC). In alternative illustrative aspects, the substrate may be Si, GaAs, SiC, GaN/SiC or other semiconductor materials known to those skilled in the art.

Another embodiment of the invention is directed to a method of encapsulating a semiconductor device of an integrated circuit (IC). The steps include providing a semiconductor IC chip including a semiconductor device and depositing a non-patterned nanocrystalline diamond or UNCD film over at least a portion of a surface of the semiconductor IC chip containing the semiconductor device to encapsulate said device. The film is deposited by a microwave plasma chemical vapor deposition process. According to an aspect, the chemical vapor deposition process is carried out in a temperature range between about 450° C. and 550° C. According to an aspect, the nanocrystalline diamond film has a thickness between about 500 nm to 10μ. In a more particular aspect, the nanocrystalline diamond film thickness is between about 1 micron (μ) to 10μ. Layer thickness will influence film opacity.

A related embodiment is directed to a method of making a tamper-proof semiconductor device package. The method involves providing a semiconductor IC chip including a semiconductor device and depositing an opaque nanocrystalline diamond film over at least a portion of a surface of the semiconductor IC chip containing the semiconductor device by a chemical vapor deposition process.

These and other objects, advantages and benefits provided by embodiments of the invention will now be set forth in detail with reference to the detailed description and the drawing figures and as defined in the appended claims.

### BRIEF DESCRIPTION OF THE DRAWINGS

FIG. 1 is a schematic perspective view of an exemplary encapsulated semiconductor device package according to an embodiment of the invention;

FIG. 2 is a schematic end cross sectional view of the exemplary encapsulated semiconductor device package illustrated in FIG. 1;

FIG. 3 is a diagrammatic top view illustrative of a hermetically sealed, tamper-proof prior art semiconductor component;

FIG. 4 is a schematic top view of an illustrative encapsulated IC according to an embodiment of the invention; and

FIGS. 5A and 5B illustrate a prior art system used for manufacturing a nanocrystalline diamond film on a substrate.

### DETAILED DESCRIPTION OF A PREFERRED EMBODIMENT OF THE INVENTION

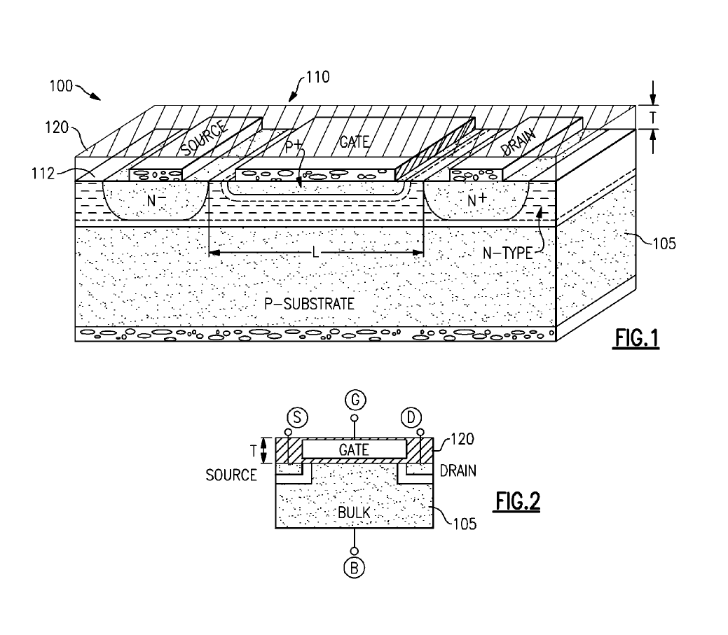

FIG. 1 illustrates an embodiment of the invention directed to an encapsulated semiconductor device package 100. The package 100 includes a semiconductor substrate 105, at least one semiconductor device illustrated in part at 110 by a source, a gate and a drain exposed on a surface 112 of the substrate, and a non-patterned encapsulating layer 120 of ultrananocrystalline diamond covering the portion of the device 110 on the exposed surface of the substrate. FIG. 2 shows an end-on cross sectional slice of the semiconductor device package. The nanocrystalline diamond film 120 has a selected nominal thickness T in the range of 550 nanometers (nm) to 10 microns (μ). In a more particular aspect, the thickness of the nanocrystalline diamond film 120 is in the range of about 1μ to 10μ. In an exemplary aspect, the individual diamond grain size of the nanocrystalline diamond film should be controlled to be less than 30 nm. The properties of the CVD deposited nanocrystalline diamond film provide a hermetic seal for the semiconductor device that it encapsulates. Furthermore, the optical and mechanical characteristics of nanocrystalline diamond (e.g., its optical opacity and hardness) provide a high level of security against tampering with the encapsulated device.

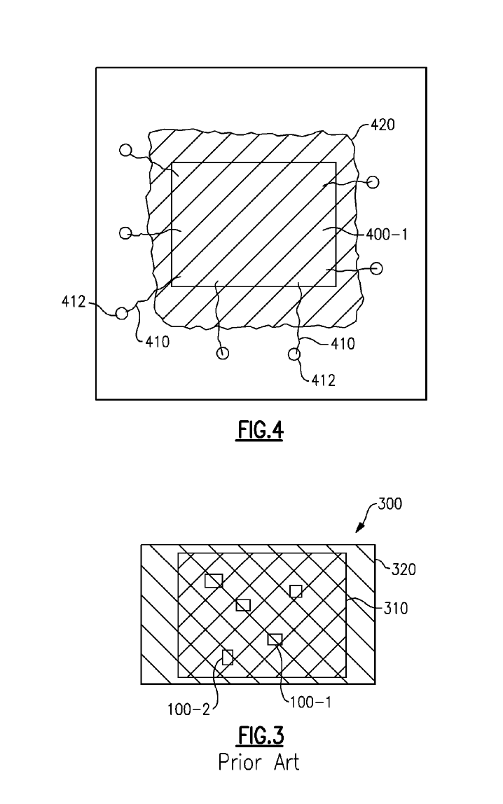

FIG. 3 illustrates an example of a traditionally encapsulated semiconductor component 300. The small squares 100-1, 100-2, etc. represent various semiconductor devices mounted on a base. A suitable epoxy resin 310 has been applied to cover the devices. A metallized or ceramic (for example) ‘can’ 320 is then soldered or otherwise affixed over the epoxy covered devices and sealed.

FIG. 4 illustrates certain advantages of the present embodiments of the invention over the prior art. A semiconductor IC 400-1 is shown with circuit traces 410 extending to various respective connections 412. A controlled thickness layer of nanocrystalline diamond 420 encapsulates the IC and portions of the circuit traces. The IC is thus hermetically sealed and at the same time is neither visible nor accessible for further inspection. Attempted removal of the nanocrystalline diamond layer would ultimately destroy the encapsulated device. These simple illustrations underscore the potential improvements in manufacturing and cost efficiency obtainable by the embodiments of the invention described and claimed herein.

Persons skilled in the art will understand that various design considerations may be necessary to achieve a desired performance from nanocrystalline diamond encapsulated semiconductor devices such as MMICs and others. For example, characteristic impedance and/or capacitance matching of the device in its nanocrystalline diamond encapsulated state should be considered due to the difference in the dielectric constant values (c) of nanocrystalline diamond, air and in vacuuo (ε₀), for example. One may wish to consider shrinking the size of the circuit features to maintain the characteristic impedance of the encapsulated device. Circuit size may likewise be adjusted to maintain a desired capacitance per unit length of the device. Ye et al., Control of grain size and size effect on the dielectric constant of diamond films, J. Phys. D: Appl. Phys. 33 No. 23 (7 Dec. 2000), the disclosure of which is hereby incorporated by reference in its entirety, suggest adjusting individual diamond grain size of the nanocrystalline diamond film to control the dielectric constant.

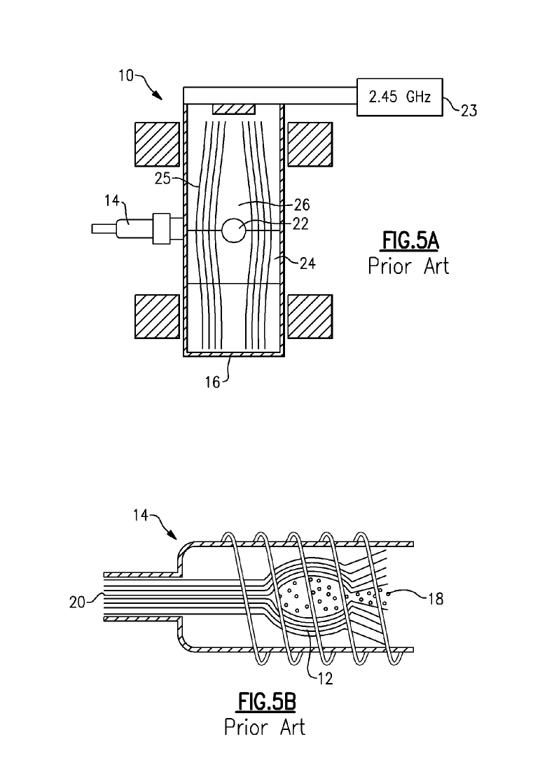

Another embodiment of the invention is directed to a method of encapsulating a semiconductor device of an integrated circuit. The method involves the steps of providing a semiconductor IC chip that includes at least one semiconductor device and depositing a non-patterned nanocrystalline diamond film over at least a portion of a surface of the semiconductor IC chip containing the semiconductor device. A method of depositing a nanocrystalline diamond film on a substrate as disclosed in U.S. Pat. No. 7,772,760, referenced hereinabove, generally involves the steps of introducing an inert gas, a hydrocarbon and from 0 to about 20 volume percent hydrogen into a chamber having a substrate therein, and forming a plasma in the chamber wherein the plasma and the gas interact to deposit a continuous nanocrystalline diamond film on the substrate. As disclosed in the '760 patent, a microwave plasma deposition system 1 0 as illustrated in FIG. 5 herein was constructed. The system 10 was based on a ASTeX (PDS-17) commercial plasma deposition apparatus manufactured by Applied Science and Technology. Fullerene containing soot 12 used as a starting material was treated to remove hydrocarbon contaminants by contact with methanol. The treated soot 12 was then thoroughly degassed by conventional vacuum and/or thermal treatment (such as heating at 200° C. for 2 hours). The degassed soot 12 was placed in a sublimator 14 which is coupled to plasma deposition chamber 16, and the volume of the sublimator 14 is also coupled to the volume of the plasma deposition chamber 16. Thus, fullerene containing vapor 18 can be introduced into the plasma deposition chamber 16 by heating the sublimator 14 (for example, by Pt resistance wire heating) to a temperature adequate to cause fullerene sublimation (such as, about 550° C. to 600° C.). A noble carrier gas (such as argon) and lower percentages (0-19%) of hydrogen were introduced through gas inlet 20 enabling the gas mixture to transport the sublimed fullerene containing vapor 18 into the plasma deposition chamber 16. A substrate 22 was used to accumulate deposited carbon as a diamond layer on the substrate 22. A suitable substrate 22 can be a single crystal silicon wafer, or one of various metals or ceramics. According to the instant embodiment, selected MMIC substrate materials include Si, GaAs, SiC, GaN/SiC or other semiconductor materials known to those skilled in the art. The substrate 22 could also be disposed on a graphite stage 24, which not only can support the substrate 22 but can act as a heating element to control the substrate temperature. Using a microwave generator 23, a microwave field 25 was established within the plasma deposition chamber 16 in order to generate an excited plasma 26. A variety of gas mixtures and other conditions were utilized to produce diamond layers.

More particularly, the '760 patent disclosed a method for manufacturing a nanocrystalline diamond film on a substrate that included the steps of: (a) forming a carbonaceous vapor from fullerene or fragments thereof and a hydrocarbon selected from CH₄, C₂, H₂ or anthracene and mixtures thereof; (b) providing a gas stream of an inert gas and hydrogen and combining the carbonaceous vapor with the gas stream; (c) passing the combined carbonaceous vapor and inert gas stream into a chamber; (d) forming a plasma in the chamber wherein the carbonaceous vapor undergoes interactions in the plasma to form carbon dimer species; and (e) depositing the carbon species onto the substrate to form a continuous, nanocrystalline diamond that essentially consists of carbon in a diamond crystallographic structure. This process and modifications made thereto as disclosed in the previously referenced patents are applicable to depositing the encapsulating nanocrystalline diamond layer on the semiconductor device according to embodiments of the invention.

In an exemplary aspect, the CVD process is controlled to provide individual grain size of the nanocrystalline diamond of less than 30 nm. In another exemplary aspect, the chemical vapor deposition process is carried out in a temperature range between about 450° C. and 550° C. The nanocrystalline diamond film is deposited in a thickness between about 500 nm to 10μ. In an exemplary aspect, the deposited thickness is between about 1μ to 10μ. The thickness may be selected to control opacity of the film, hemeticity, tamper-proof characteristics, and for other reasons determined by a particular use or application of the semiconductor component.

The foregoing description of the embodiments of the invention have been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. An encapsulated semiconductor device package, comprising:
a semiconductor substrate;
at least one semiconductor device wherein a portion of the device is on an exposed surface of the substrate; and
a non-patterned layer of nanocrystalline diamond covering the portion of the device on the exposed surface of the substrate.

2. The semiconductor device package of claim 1, wherein the layer of nanocrystalline diamond is hermetic.

3. The semiconductor device package of claim 1, wherein the layer of nanocrystalline diamond has individual diamond grain size of less than 30 nm.

4. The semiconductor device package of claim 1, wherein the layer of nanocrystalline diamond is opaque in the visible wavelength range.

5. The semiconductor device package of claim 1, wherein the layer of nanocrystalline diamond has a nominal thickness in the range of 550 nanometers (nm) to 10 microns (μ).

6. The semiconductor device package of claim 5, wherein the nominal thickness is in the range of about 1μ to 1μ.

7. The semiconductor device package of claim 1, wherein the at least one semiconductor device is a microwave monolithic integrated circuit (MMIC).

8. The semiconductor device package of claim 7, wherein the substrate is one of Si, GaAs, SiC and GaN/SiC.

9. The semiconductor device package of claim 1, wherein the device has a characteristic impedance value that is matched with a characteristic impedance value of the device in a non nanocrystalline diamond encapsulated state.

10. The semiconductor device package of claim 1, wherein the device has a characteristic capacitance per unit length value that is matched with a characteristic capacitance per unit length value of the device in a non nanocrystalline diamond encapsulated state.

11. A method of encapsulating a semiconductor device of an integrated circuit (IC), comprising:
providing a semiconductor IC chip including a semiconductor device; and
depositing a non-patterned nanocrystalline diamond film over at least a portion of a surface of the semiconductor IC chip containing the semiconductor device.

12. The method of claim 11, comprising controlling the individual grain size of the nanocrystalline diamond to be less than 30 nm.

13. The method of claim 11, comprising hermetically sealing the at least a portion of a surface of the semiconductor IC chip containing the semiconductor device.

14. The method of claim 11, wherein the film is deposited by a microwave plasma chemical vapor deposition process.

15. The method of claim 11, wherein the chemical vapor deposition process is carried out in a temperature range between about 450° C. and 550° C.

16. The method of claim 11, comprising depositing a nanocrystalline diamond film in a thickness between about 500 nm to 10μ.

17. The method of claim 17, wherein the thickness is between about 1μ to 10μ.

18. A method of making a tamper-proof semiconductor device package, comprising:
providing a semiconductor IC chip including a semiconductor device; and
depositing a nanocrystalline diamond film over at least a portion of a surface of the semiconductor IC chip containing the semiconductor device by a chemical vapor deposition process, wherein the nanocrystalline diamond film has a thickness rendering it optically opaque.
